(19) United States
(12) Patent Application Publication
(10) Pub. No.: US 2011/0267073 A1
(43) Pub. Date: Nov. 3, 2011

(54) VALIDATING HIGH SPEED LINK PERFORMANCE MARGIN FOR SWITCH FABRIC WITH ANY-TO-ANY CONNECTION ACROSS A MIDPLANE

(75) Inventors: David P. CHENGSON, Aptos, CA (US); Granthana Rangaswamy, Sunnyvale, CA (US)

(73) Assignee: Juniper Networks, Inc., Sunnyvale, CA (US)

(21) Appl. No.: 12/769,749

(22) Filed: Apr. 29, 2010

(51) Int. Cl. G01R 27/28

(52) U.S. Cl. 324/628

(57) ABSTRACT

A system for testing link performance margin in a network device includes one or more daughter cards having a driver to transmit a signal and a receiver to receive the signal, and a midplane including a channel to transmit the signal from the driver to the receiver. The system includes multiple connector assemblies to connect the one or more daughter cards to the midplane, where each of the multiple connector assemblies includes a different known crosstalk margin value. A bit error rate tester is connected to a link between the driver and the receiver, and the multiple connector assemblies are interchangeably included in the link to approximate different signal-to-noise ratio margins for the tested link.

### BACKGROUND

System crosstalk in network devices can become a significant problem as system speed increases. In contrast with channel loss, which can be equalized out, channel crosstalk cannot be equalized out. Thus, elimination of channel crosstalk remains a challenge as the signal to crosstalk noise ratio decreases and speed increases. For a switch fabric with any-to-any connectivity, this problem becomes more significant and complicated as crosstalk from connectors in a midplane can have the same aggressors crosstalking to the same victim in multiple connectors in a signal path. Testing and validating that an entire link through a system has sufficient margin and acceptable bit error rate (BER) can be a challenge given the range of variables, such as process, voltage, and temperature effects.

### SUMMARY

According to one aspect, a system for testing link performance margin in a network device may include one or more daughter cards including a driver to transmit a signal and a receiver to receive the signal, and a midplane including a channel to transmit the signal from the driver to the receiver. The system may further include multiple connector assemblies to connect the one or more daughter cards to the midplane, where each of the multiple connector assemblies includes a different known crosstalk margin value, and a bit error rate tester operatively connected to a link between the driver and the receiver, where the multiple connector assemblies may be interchangeably included in the link to approximate different signal-to-noise ratio margins for the link.

According to another aspect, a method for testing link performance margin in a network device may include selecting a network device link to test, where the link includes a driver that sends a signal to a receiver via a midplane, and providing multiple connector assemblies to the midplane, where each of the multiple connector assemblies includes a different known crosstalk margin value. The method may also include performing bit error rate testing of the link using the multiple connector assemblies, where the multiple connector assemblies approximate different signal-to-noise ratio margins for the link, and identifying a maximum acceptable signal-to-noise ratio margin for the link based on the bit error rate testing.

According to still another aspect, a test platform for a network device may include a midplane of the network device; a driver to send a signal through the midplane at a particular frequency, and a receiver to receive the signal from the midplane at the particular frequency. The test platform may also include multiple differential connector assemblies, where each of the multiple differential connector assemblies may be configured to connect the driver or the receiver to the midplane, and where each of the multiple connector assemblies may include a different known crosstalk margin value for the particular signal frequency. The test platform may also include a bit error rate tester operatively connected to a link between the driver and the receiver, where the multiple connector assemblies may be interchangeably included in the link to approximate different signal-to-noise ratio margins for the link at the particular frequency.

### BRIEF DESCRIPTION OF THE DRAWINGS

The accompanying drawings, which are incorporated in and constitute a part of this specification, illustrate one or more implementations described herein and, together with the description, explain these implementations. In the drawings:

FIG. 1 is a diagram of a representative system in which systems and/or methods described herein may be implemented;

FIG. 2 is a perspective view illustrating a representative physical layout of a portion of the network device of FIG. 1;

FIG. 3 is a perspective view illustrating a representative physical layout of a connector assembly of FIG. 2;

FIG. 4 is block diagram illustrating an example configuration of a test platform for determining crosstalk margin for a connector assembly according to an implementation described herein;

FIG. 5 is a block diagram illustrating a representative configuration of a test platform with a channel connecting a flexible PIC concentrator to a packet processor card across a midplane; and

FIGS. 6 and 7 are flow charts of an example process for validating high speed link performance margin for a network device according to an implementation described herein.

### DETAILED DESCRIPTION

The following detailed description refers to the accompanying drawings. The same reference numbers in different drawings may identify the same or similar elements. Also, the following detailed description does not limit the invention.

Implementations described herein may provide systems and/or methods that validate high speed link performance margin for a switch fabric with any-to-any connection across a midplane. System connector crosstalk may be a limiting factor for high speed (e.g., in the range of 6 gigabits per second (Gb/s)) operation in a switch fabric router with any-to-any connectivity across the midplane. In implementations described herein, validating and testing a system design can be accomplished by increasing the system connector crosstalk in a deterministic manner. For example, the connector crosstalk may be increased by a selected increment (e.g., 5 dB) at a known frequency (e.g., at a predominate frequency of an edge rate of the signal). The signal to noise ratio can be deterministically margined by 5 dB, and bit error rate validation testing can be done that can better account for unknown process corner of silicon and channel effects by estimating this variation in terms of a signal to noise ratio margin. The term “process corner,” as used herein, may refer to a combination of process parameter extremes. Thus, a process corner may be a vector of extreme values of all process parameters under consideration.

More particularly, high speed differential connectors can have crosstalk due to imperfect shielding inherent to their design. Physically modifying the metal shield structure between the columns of differential pair pins of the connector can increase/decrease crosstalk in the connector. By measuring this crosstalk increase/decrease using, for example, a vector network analyzer (VNA) and determining the decibel crosstalk increase at the predominate frequency of the edge rate of the signal, the delta in crosstalk with the connector metal shield structure modification can be determined. By applying this technique to a set of different connectors, different amounts of crosstalk margin for connectors can be deterministically created. These deterministic crosstalk connectors can then be used in the testing and validation of a system link with a deterministic margin in signal to noise ratio.

### Representative Device

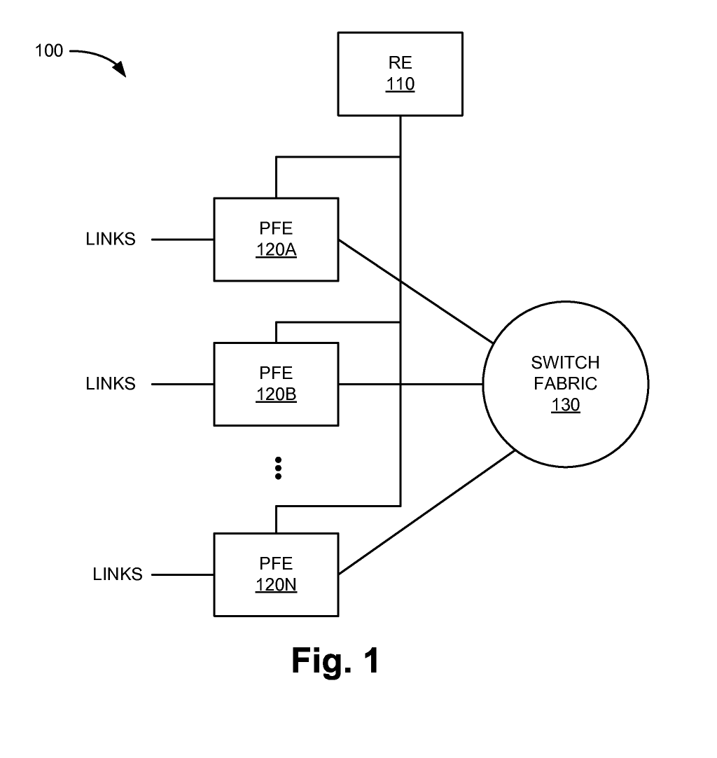

FIG. 1 is a diagram of an exemplary network device 100 in which systems and/or methods described herein may be implemented. In this particular implementation, network device 100 may take the form of a router, although the principles of the invention may be applied in another type of system or device. For example, network device 100 may include a data transfer device, such as a gateway, a router, a switch, a firewall, a network interface card (NIC), a hub, a bridge, a proxy server, an optical add-drop multiplexer (OADM), or some other type of device that processes and/or transfers traffic.

Network device 100 may receive one or more packet streams (or streams of data in other formats) from physical links, processes the packet stream(s) to determine destination information, and may transmit the packet stream(s) out on links in accordance with the destination information. Network device 100 may include a routing engine (RE) 110, packet forwarding engines (PFEs) 120A, 120B, . . . , 120N (referred to collectively as “PFEs 120” and generically referred to as “PFE 120”), and a switch fabric 130.

RE 110 may perform high level management functions for network device 100. For example, RE 110 may maintain the connectivity and manages information and data necessary for performing routing by network device 100. RE 110 may create routing tables based on network topology information, create forwarding tables based on the routing tables, and communicate the forwarding tables to PFEs 120. PFEs 120 may use the forwarding tables to perform route lookup for incoming packets and perform the forwarding functions for network device 100. RE 110 may also perform other general control and monitoring functions for network device 100.

Each of PFEs 120 may be connected to RE 110 and switch fabric 130. PFEs 120 may receive packet data on physical links connected to a network, such as a wide area network (WAN) or a local area network (LAN). Each physical link could be one of many types of transport media, such as optical fiber or Ethernet cable.

PFEs 120 may process incoming packet data prior to transmitting the data to another PFE or the network. PFEs 120 may also perform route lookups for the data using the forwarding table from RE 110 to determine destination information. If the destination indicates that the data should be sent out on a physical link connected to one of PFEs 120, then PFE 120 prepares the data for transmission by, for example, adding any necessary headers, and transmits the data from the port associated with the physical link. If the destination indicates that the data should be sent to another PFE 120 via switch fabric 130, then PFE 120 prepares the data for transmission to the other PFE 120, if necessary, and sends the data to the other PFE 120 via switch fabric 130.

Switch fabric 130 may include one or multiple switching planes to facilitate communication among PFEs 120 and/or RE 110. In one implementation, each of the switching planes may include a single-stage switch or a multi-stage switch of crossbar elements. Switch fabric 130 may also, or alternatively, include processors, memories, and/or paths that permit communication among RE 110, PFEs 120, and the line interfaces.

Although, FIG. 1 illustrates exemplary components of network device 100, in other implementations, network device 100 may include additional components, fewer components, different components, or differently arranged components than those illustrated in FIG. 1 and described herein. Additionally, or alternatively, one or more operations described as being performed by a particular component of network device 100 may be performed by one or more other components, in addition to or instead of the particular component of network device 100.

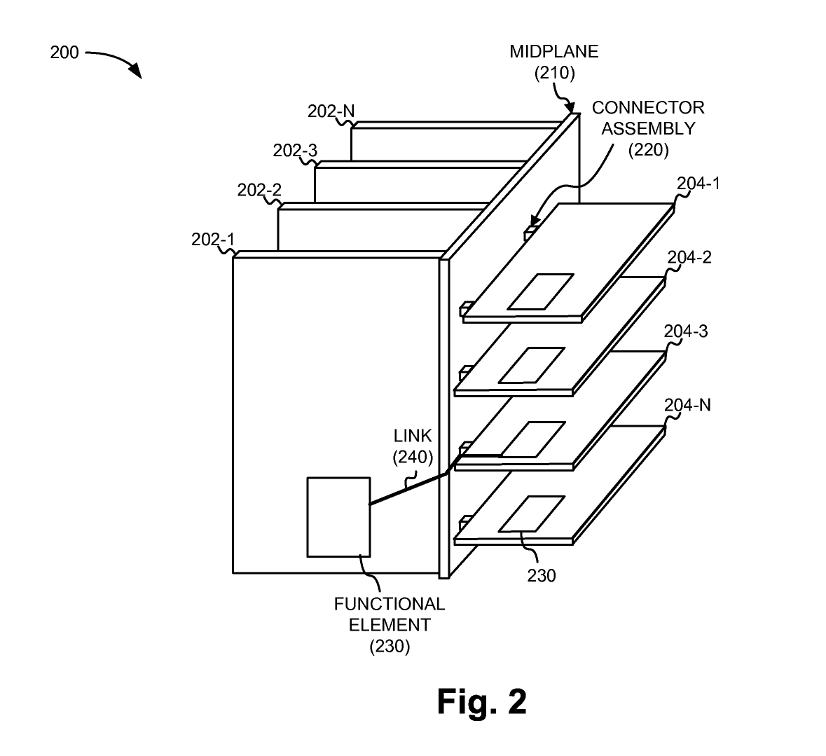

FIG. 2 is a perspective view illustrating a representative physical layout of a portion 200 of network device 100. Portion 200 may include one or more PFEs 120 implemented in one or more circuit boards. PFE 120 may include programmable interface cards (PICs) (not shown), flexible PIC concentrators (FPCs) 202-1 through 202-N (referred to collectively as “FPCs 202” and generically as “FPC 202”), and packet processor cards 204-1 through 204-N (referred to collectively as “packet processor cards 204” and generically as “packet processor card 204”). FPCs 202 and packet processors 204 may be inserted into a midplane 210 that connects FPCs 202 and packet processors 204 to other FPCs 202 and packet processors 204.

In one implementation, midplane 210 may include a circuit board that provides any-to-any connections between FPCs 202 and packet processor cards 204. In another implementation midplane 210 may be connected to one more power supplies (not shown), and midplane 210 may distribute power to other circuit boards (e.g., FPCs 202 and packet processor cards 204).

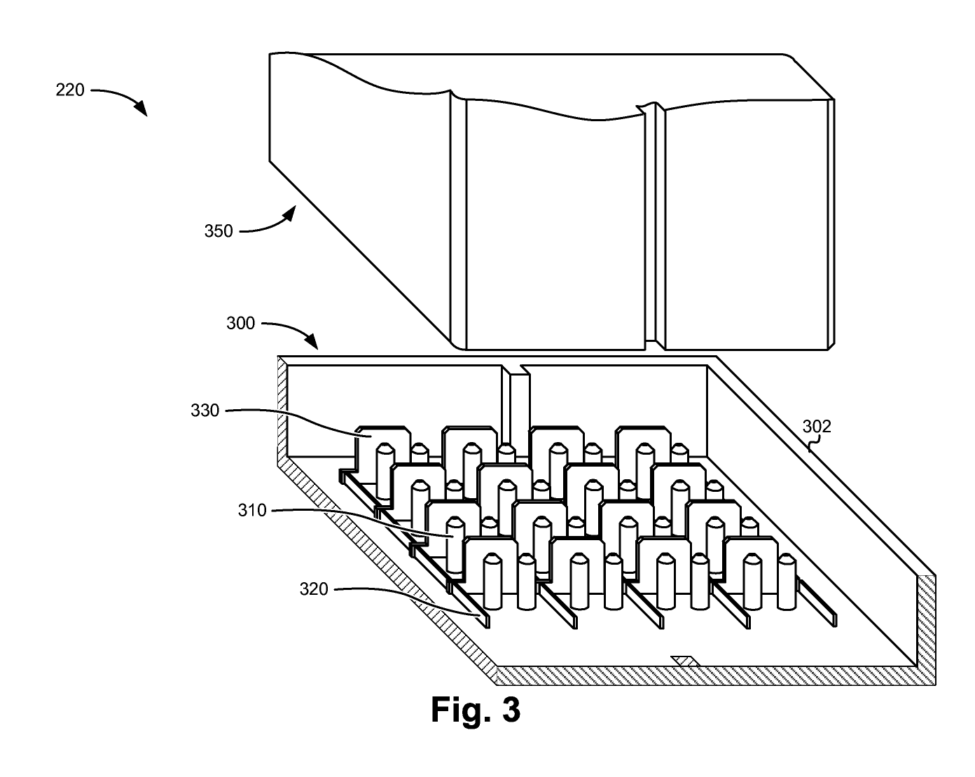

Midplane 210 may have a first side and a second side. FPCs 202-1, 202-2, 202-3 and 202-N may be electrically connected to midplane 210 on the first side, while packet processor cards 204-1, 204-2, 204-3, and 204-N may be electrically connected to midplane 210 on the second side. While FPCs 202 on the first side of midplane 210 are shown orthogonal in orientation to the packet processor cards 204 on the second side of midplane 210, other orientations of FPCs 202 and packet processor cards 204 may be used. FPCs 202 and packet processor cards 204 may be electrically connected to midplane 210 by electrical connector assemblies 220, which are described in more detail in connection with, for example, FIG. 3. Midplane 210 may include multiple signal traces that route signals between circuits within FPCs 202 and packet processor cards 204 to provide, for example, any-to-any connectivity between FPCs 202 and packet processor cards 204.

FPC 202 and packet processor card 204 may include multiple functional elements 230, such as application specific integrated circuits (ASICs), field programmable gate arrays (FPGAs), or the like. A connection between particular functional elements 230 within FPC 202 and packet processor card 204 (or another FPC 202) may be referred to as a link, such as link 240 between functional element 230 of FPC 202-1 and functional element 230 of packet processor card 204-3. A portion of a link that passes through midplane 210 may be referred to as a channel.

Although, FIG. 2 illustrates a representative physical layout of portion 200, in other implementations, portion 200 may include additional components, fewer components, different components, or differently arranged components than those illustrated in FIG. 2 and described herein. For example, while portion 200 is shown with midplane 210 between FPCs 202 and packet processor cards 204, in other implementations midplane 210 may be used to connect other types of circuit boards or cards (e.g., generically referred to herein as daughter cards). Additionally, or alternatively, one or more operations described as being performed by a particular component of portion 200 may be performed by one or more other components, in addition to or instead of the particular component of portion 200.

FIG. 3 shows a representative connector assembly 220 according to an implementation described herein. Connector assembly 220 may be used to connect FPCs 202 and/or packet processor cards 204 to midplane 210. In one implementation, connector assembly 220 may be a differential electrical connector. The connector assembly 220 may include a first differential electrical connector 300, which may be connected to midplane 210 (not shown), and a second differential electrical connector 350, which connects to one of FPCs 202 or packet processor cards 204 (not shown). Typically, one or more second connectors 350 would be connected to each FPC 202/packet processor card 204, with the corresponding number of first connectors 300 connected to the midplane 210.

First differential electrical connector 300 may include a housing 302 (shown partially cut away for clarity), which may be made of an insulating material. A group of signal conductors 310, a group of ground conductors 320, and a group of vertical shields 330 may be disposed in a base of housing 302. Signal conductors 310 may be provided as differential pairs, and a set of ground conductors 320 and vertical shields 330 may correspond to a differential pair of signal conductors 310. Each vertical shield 330 may be positioned and configured to shield a corresponding differential pair of signal conductors 310 from the electromagnetic effects of adjacent signal conductor pairs.

Physically altering a vertical shield 330 (e.g., altering from the original equipment manufacture (OEM) condition) may alter the crosstalk effects of a corresponding differential pair of signal conductors 310. For example, removing (e.g., using tin snips) or bending a portion of vertical shield 330 may increase crosstalk for a pair of signal conductors 310. As described further herein, crosstalk levels may be measured after such physical modifications to vertical shield 330 in order to create modified connectors with known crosstalk margins.

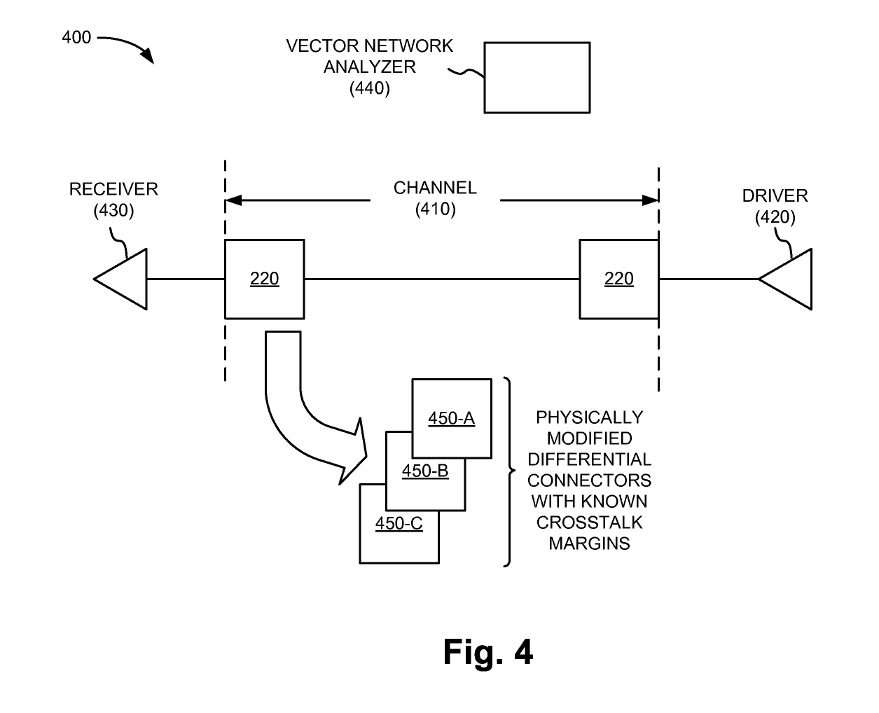

FIG. 4 provides a block diagram illustrating an example configuration of a test platform 400 for determining crosstalk margin for a pair of connector assemblies 220. As illustrated, test platform 400 may form a channel 410 for transmitting signals at a particular frequency between a driver 420 and a receiver 430. A vector network analyzer 440 may be used to characterize channel 410 in the frequency domain. This characterization may illustrate the effects of crosstalk on channel 410 generally and on pair of connector assemblies 220 particularly.

In operation, a signal frequency for the link in test platform 400 may be selected, using, for example, the predominate frequency associated with the edge rate of the signal over a particular link in a network device to be tested. Vector network analyzer 440 in test platform 400 may be used to measure the crosstalk (in dB) in the link between driver 420 and receiver 430 at the selected frequency. While vector network analyzer 440 may provide a signal-to-noise ratio for the entire channel 410, noise may be assumed to be connector crosstalk noise for purposes of establishing a baseline.

A portion of one of connector assemblies 220—particularly differential connector 300—may be physically modified to create a modified connector assembly 450-A with altered crosstalk properties. Differential connector 300 may be altered, for example, by bending and/or clipping vertical shields 330 to create different shielding properties for signal conductors 310 within differential connector 300. The modified connector assembly 450-A may replace one connector assembly 220 and may be tested on test platform 400 using vector network analyzer 440. In other implementations, both connector assemblies 220 (e.g., one near driver 420 and one near receiver 430) may be modified. Vector network analyzer 440 may measure the signal-to-noise ratio across channel 410, including the connector assembly pair of the modified connector assembly 450-A and the unmodified connector assembly 220. The signal-to-noise ratio of connector assembly pair (e.g., including connector assembly 220 with modified connector assembly 450-A) across channel 410 may be compared to the previously established baseline to determine an incremental crosstalk difference when using modified connector assembly 450-A.

A user may determine if the incremental crosstalk difference of modified connector assembly 450-A provides a margin that will be useful for subsequent BER testing. In one implementation, a user may create multiple modified connector pairs (e.g., connector assemblies 450-A, 450-B, 450-C, etc. paired with a connector 220), each with a different amount of crosstalk margin, such that the modified connector pairs can represent a series of known incremental crosstalk noise increases (e.g., at about 5 dB increments) for a particular frequency. Thus, an acceptable incremental crosstalk difference for a particular modified connector pair may be one that has a quantifiable increase/decrease (e.g., 5 dB, 10 dB, etc.) over a baseline measurement.

Although, FIG. 4 illustrates a representative test platform 400, in other implementations, test platform 400 may include additional components, fewer components, different components, or differently arranged components than those illustrated in FIG. 4 and described herein. Additionally, or alternatively, one or more operations described as being performed by a particular component of test platform 400 may be performed by one or more other components, in addition to or instead of the particular component of test platform 400.

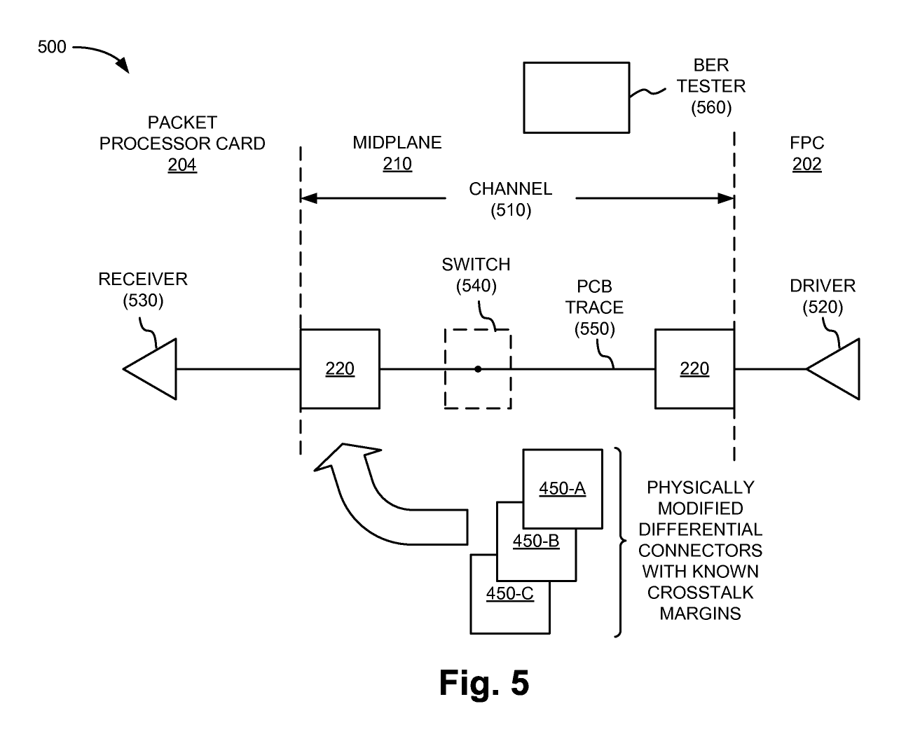

FIG. 5 provides a block diagram illustrating a representative configuration of a test platform 500 with a channel 510 connecting a FPC 202 to a packet processor card 204 in an implementation. For example, channel 510 may correspond to channel 230 connecting FPC 202-1 and packet processor card 204-3 of FIG. 3. While the foregoing description focuses on transmitting signals from FPC 202 to packet processor card 204, the techniques described herein are equally applicable to the transmission of signals from packet processor card 204 to FPC 202. Moreover, the links connecting FPC 202 to packet processor card 204 may be bi-directional. As such, FPC 202 and packet processor card 204 may be configured to send and receive signals.

When operated at very high speeds (e.g., speeds on the order of 6 Gb/s) a variable that effects transmission bandwidth through channel 510 is crosstalk. Generally, crosstalk is the electrical interference in a channel caused by a signal traveling through a neighboring channel. Under some circumstances, the presence of unwanted crosstalk can be the limiting speed factor for system performance. Thus, in systems employing differential pin pair connections, it can be important that connector assemblies 220 are designed and tested with deterministically margined increments of crosstalk to better account for unknown process corners and channel effects.

As illustrated in FIG. 5, FPC 202 may include a driver 520 for transmitting signals to a receiver 530 of packet processor card 204. In one implementation driver 520 and receiver 530 may each include a serializer/deserializer (serdes) transceiver. Driver 520 may include a digital finite response filter (FIR) and receiver 530 may include a decision-feedback equalizer (DFE) that both compensate for intersymbol interference (ISI) jitter and reflections in the transmission line connecting driver 520 to receiver 530. In one implementation, channel 510 may be a high speed (e.g., 6 Gb/S or greater) source synchronous channel. Channel 510 may include connector assemblies 220 (e.g., connector assemblies to enter and exit midplane 210), and a switch 540 that acts to selectively transfer signals from driver 520 (or another driver, not shown) based on a control signal received at switch 540. In one implementation, switch 540 may include for example n-channel FETs or another electronic, mechanical, and/or optical switch configuration/type.

In operation, a system link may be selected for test platform 500. The system link may include generally silicon transmitting (Tx) and receiving (Rx) serdes, and a channel that includes a PCB and connector assemblies for the midplane. In the particular configuration of FIG. 5, the system link may include driver 520, receiver 530, switch 540, two connector assemblies 220, and PCB traces 550 connecting each element in the link. A set of physically modified connector assemblies 450-A, 450-B, and 450-C with known crosstalk margins may be provided. Connector assemblies 450-A, 450-B, and 450-C may have incrementally increasing crosstalk margins as experimentally derived, for example, from tests on test platform 400. One of connector assemblies 450-A, 450-B, and 450-C may be paired with one of connector assemblies 220, and BER testing may be conducted by a BER tester 560.

The BER testing may result in a particular bit error rate for the test link. The bit error rate may be within or exceed a selected threshold (e.g., 99.99 percent). If the BER using one connector (e.g., connector assembly 450-A) is acceptable, a user may select another connector (e.g., connector assembly 450-B) to determine if link performance can still meet the BER threshold with a known amount of increased crosstalk through channel 510. If the BER is not acceptable for a particular connector (e.g., connector assembly 450-B), the crosstalk margin from the first/previous connector (e.g., connector assembly 450-A) may be applied as the signal-to-noise ratio limit for the tested link. Conversely, if a tested bit error rate exceeds the selected threshold using a particular connector (e.g., connector assembly 450-B) in channel 510, a user may then select a connector with a higher margin (e.g., connector assembly 450-C) and continue testing accordingly until a BER test failure occurs.

Although, FIG. 5 illustrates a representative test platform 500, in other implementations, test platform 500 may include additional components, fewer components, different components, or differently arranged components than those illustrated in FIG. 5 and described herein. Additionally, or alternatively, one or more operations described as being performed by a particular component of test platform 500 may be performed by one or more other components, in addition to or instead of the particular component of test platform 500.

### Example Process

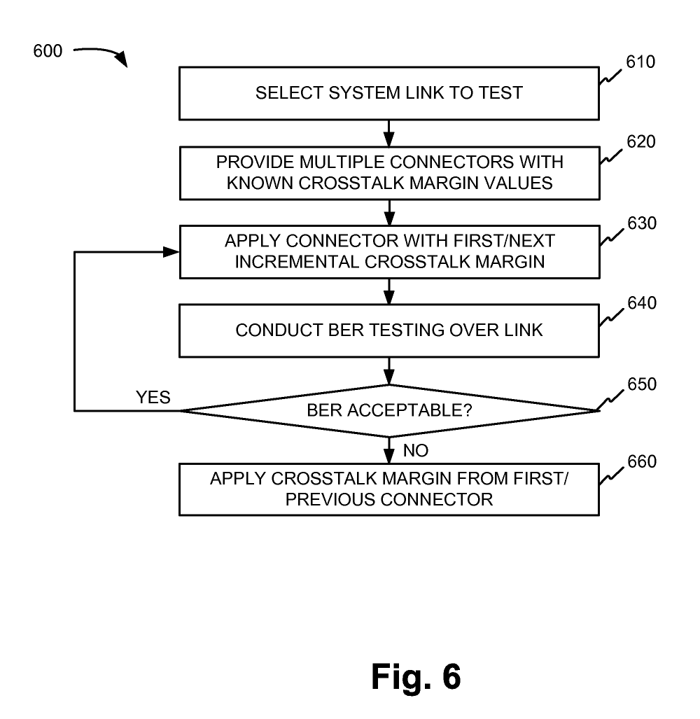

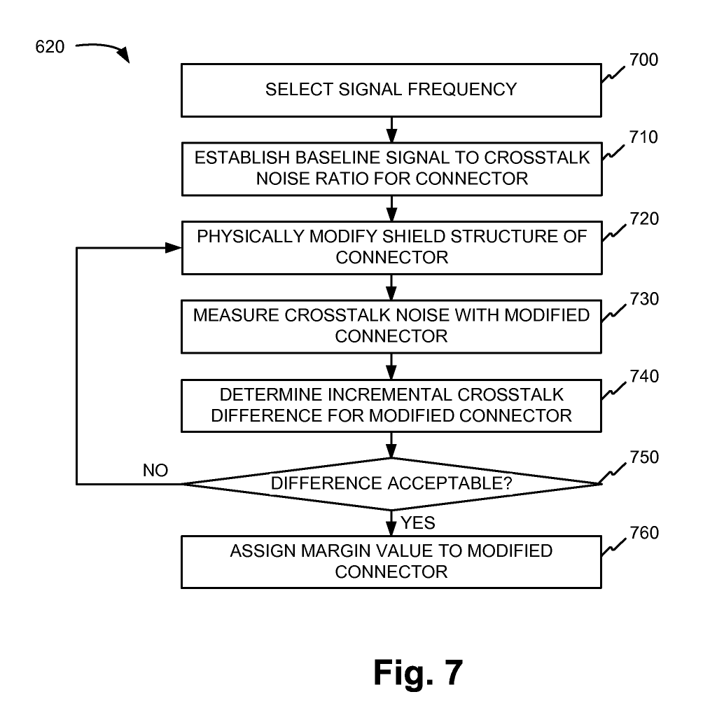

FIGS. 6 and 7 are flow charts of an exemplary process 600 for validating high speed link performance margin for a network device according to an implementation described herein. In one implementation, process 600 may be performed using test platform 500. In another implementation, process 600 may be performed using test platform 500 in conjunction with one or more other test platforms, such as test platform 400.

As illustrated in FIG. 6, process 600 may include selecting a system link to test (block 610) and providing multiple connectors with known crosstalk margin values (block 620). For example, in implementations described above in connection with FIG. 5, a system link may be selected for test platform 500. The system link may include generally silicon transmitting (Tx) and receiving (Rx) serdes, and a channel that includes a PCB and connector assemblies for the midplane. The system link may include driver 520, receiver 530, switch 540, two connector assemblies 220, and PCB traces 550 connecting each element in the link. A set of physically modified connectors assemblies 450-A, 450-B, and 450-C with known crosstalk margins may be provided. Connectors assemblies 450-A, 450-B, and 450-C may have incrementally increasing crosstalk margins as experimentally derived, for example, from tests on test platform 400.

Returning to FIG. 6, process 600 may include applying a connector with a first/next incremental crosstalk margin (block 630) and conducting BER testing over the link (block 640). For example, in implementations described above in connection with FIG. 5, one of connector assemblies 450-A, 450-B, and 450-C may be paired with one of connector assemblies 220, and BER testing may be conducted.

Referring again to FIG. 6, it may be determined if the BER is acceptable (block 650). For example, in implementations described above in connection with FIG. 5, BER testing may result in a particular bit error rate for the test link. The bit error rate may be within or exceed a selected threshold (e.g., 99.99 percent). If the BER is acceptable (block 650—YES), process 600 may return to block 630 to apply a connector with a next incremental crosstalk margin. For example, a user may select another connector (e.g., connector assembly 450-B) to determine if link performance can still meet the BER threshold with a known amount of increased crosstalk through channel 510. If the BER is not acceptable (block 650—NO), the crosstalk margin from the first/previous connector may be applied (block 660). For example, in implementations described above in connection with FIG. 5, a tested bit error rate may exceed the selected threshold using a particular connector 420 (e.g., connector assembly 450-B) in channel 510. A user may then select the margin associated with the next lower connector (e.g., connector assembly 450-A) as the signal-to-noise ratio limit for the tested link.

Process block 620 may include the process blocks depicted in FIG. 7. As illustrated in FIG. 7, process block 620 may include selecting a signal frequency for a link (block 700). For example, in implementations described above in connection with FIG. 4, a signal frequency for the link may be selected, using, for example, the predominate frequency associated with the edge rate of the signal over a particular link in a network device.

As further shown in FIG. 7, process block 620 may include establishing a baseline signal-to-crosstalk-noise ratio for the connector (block 710). For example, in implementations described above in connection with FIG. 4, vector network analyzer 440 in test platform 400 may be used to measure the crosstalk (in dB) in the link between driver 420 and receiver 430 at the selected frequency. While vector network analyzer 440 may provide a signal-to-noise ratio for the entire channel 410, noise may be assumed to be connector crosstalk noise for purposes of establishing a baseline.

Returning again to FIG. 7, process 620 may include physically modifying the shield structure of the connector (block 720), measuring the crosstalk noise for the modified connector (block 730), and determining the incremental crosstalk difference for the modified connector (block 740). For example, in implementations described above in connection with FIG. 4, a portion of connector assembly 220—particularly differential connector 300—may be physically modified to create modified connector assembly 450-A with altered crosstalk properties. Differential connector 300 may be altered, for example, by bending and/or clipping vertical shields 330 to create different shielding properties for signal conductors 310 within differential connector 300. Modified conductor assembly 450-A may be paired with connector assembly 220 and may be tested on test platform 400 using VNA 440. VNA 440 may measure the signal-to-noise ratio across channel 410, including the connector assembly pair of the modified connector assembly 450-A and the unmodified connector assembly 220. The signal-to-noise ratio of connector assembly 220 with modified connector assembly 450-A may be compared to the previously established baseline to determine an incremental crosstalk difference from modified connector assembly 450-A.

Referring back to FIG. 7, it may be determined if the incremental crosstalk difference is acceptable (block 750). For example, in implementations described above in connection with FIG. 4, a user may determine if the incremental crosstalk difference of modified connector assembly 450-A provides a margin that will be useful for subsequent BER testing. In one implementation, a user may create multiple modified connectors (e.g., connector assemblies 450-A, 450-B, 450-C, etc.), each with a different amount of crosstalk margin, such that the modified connectors can represent a series of known incremental increases (e.g., at about 5 dB increments). Thus, an acceptable incremental crosstalk difference for a particular modified connector may be one that has a quantifiable increase/decrease (e.g., 5 dB, 10 dB, etc.) over a baseline measurement. If the difference is not acceptable (block 750—NO), process block 620 may return to block 720 to further physically modify the shield structure of the connector. If the difference is acceptable (block 750—YES), the margin values may be assigned to the modified connector (block 760). For example, a particular value (e.g., +10 dB) may be assigned to the modified connector, based on the incremental crosstalk difference that was measured for that connector.

### CONCLUSION

Implementations described herein may include systems and/or methods for testing link performance margin in a network device. The systems and/or methods may include one or more daughter cards having a driver to transmit a signal and a receiver to receive the signal, and a midplane including a channel to transmit the signal from the driver to the receiver. The systems and/or methods may also include multiple connector assemblies to connect the one or more daughter cards to the midplane, where each of the multiple connector assemblies includes a different known crosstalk margin value. A bit error rate tester may be connected to a link between the driver and the receiver, and the multiple connector assemblies may be interchangeably included in the link to approximate different signal-to-noise ratio margins for the tested link. Thus, the multiple connector assemblies may provide a deterministic margin in signal-to-noise ratio for testing and validating the link.

The systems and/or methods described herein may permit network devices with switch fabric links in an any-to-any connectivity system to be tested and validated with a deterministic and known signal-to-noise ratio margin. Therefore, a higher quality product can be designed and validated.

The foregoing description of implementations provides illustration and description, but is not intended to be exhaustive or to limit the invention to the precise form disclosed. Modifications and variations are possible in light of the above teachings or may be acquired from practice of the invention.

For example, while series of blocks have been described with regard to FIGS. 6 and 7, the order of the blocks may be modified in other implementations. Further, non-dependent blocks may be performed in parallel.

It will be apparent that exemplary aspects, as described above, may be implemented in many different forms of software, firmware, and hardware in the embodiments illustrated in the figures. The actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the disclosure of the invention. In fact, many of these features may be combined in ways not specifically recited in the claims and/or disclosed in the specification.

No element, act, or instruction used in the present application should be construed as critical or essential to the invention unless explicitly described as such. Also, as used herein, the article “a” is intended to include one or more items. Where only one item is intended, the term “one” or similar language is used. Further, the phrase “based on” is intended to mean “based, at least in part, on” unless explicitly stated otherwise.

What is claimed is:

1. A system for testing link performance margin in a network device, comprising:
one or more daughter cards including a driver to transmit a signal and a receiver to receive the signal;
a midplane including a channel to transmit the signal from the driver to the receiver,
multiple connector assemblies to connect the one or more daughter cards to the midplane, where each of the multiple connector assemblies includes a different known crosstalk margin value; and
a bit error rate tester operatively connected to a link between the driver and the receiver, where the multiple connector assemblies are interchangeably included in the link to approximate different signal-to-noise ratio margins for the link.

2. The system of claim 1, where each of the multiple connector assemblies include a differential pin pair and a shield structure, and where the shield structure is physically modified from an original equipment manufacturer (OEM) condition to alter the crosstalk levels of the differential pin pair.

3. The system of claim 2, where the physically modified shield structure includes removal of or bending of a portion of the shield structure.

4. The system of claim 2, where the crosstalk level is determined based on a vector network analyzer measurement at a particular signal frequency.

5. The system of claim 3, where the particular signal frequency corresponds to a predominate frequency of an edge rate of a signal over the link.

6. The system of claim 1, where each of multiple connector assemblies includes a different incremental increase, over a baseline measurement, of measured crosstalk noise levels at a particular frequency.

7. The system of claim 1, where the connector assemblies are high speed differential connector assemblies.

8. The system of claim 1, where the network device comprises one or more of:
a gateway,
a router,
a switch,
a firewall,
a hub,
a bridge,
a proxy server, or
an optical add-drop multiplexer (OADM).

9. A method for testing link performance margin in a network device, comprising:
selecting a network device link to test, where the link includes a driver that sends a signal to a receiver via a midplane;
providing multiple connector assemblies to the midplane, where each of the multiple connector assemblies includes a different known crosstalk margin value;
performing bit error rate testing of the link using the multiple connector assemblies, where the multiple connector assemblies approximate different signal-to-noise ratio margins for the link; and
identifying a maximum acceptable signal-to-noise ratio margin for the link based on the bit error rate testing.

10. The method of claim 9, where the connector assemblies are high speed differential connector assemblies.

11. The method of claim 9, where the providing multiple connector assemblies comprises:
establishing a baseline signal-to-crosstalk-noise ratio, at a particular frequency, for one of the multiple connector assemblies;
physically modifying a shield structure of the one of the multiple connector assemblies;
measuring a signal-to-crosstalk-noise ratio, at the particular frequency, for the modified connector assembly; and
determining an incremental crosstalk difference for the modified connector assembly.

12. The method of claim 11, where the physically modifying the shield structure includes removing or bending a portion of the shield structure.

13. The method of claim 11, where the measuring the signal-to-crosstalk noise ratio is performed using a vector network analyzer.

14. The method of claim 9, where each of multiple connector assemblies includes a different incremental increase, over a baseline measurement, of measured crosstalk noise levels at a particular frequency.

15. The method of claim 14, where the particular frequency corresponds to the predominate frequency of the edge rate of the signal.

16. The method of claim 9, where the network device comprises one or more of:
a gateway,
a router,
a switch,
a firewall,
a hub,
a bridge,
a proxy server, or
an optical add-drop multiplexer (OADM).

17. A test platform for a network device, comprising:
a midplane of the network device;
a driver to send a signal through the midplane at a particular frequency;
a receiver to receive the signal from the midplane at the particular frequency;
multiple differential connector assemblies, where each of the multiple differential connector assemblies are configured to connect the driver or the receiver to the midplane, and where each of the multiple connector assemblies includes a different known crosstalk margin value for the particular signal frequency; and
a bit error rate tester operatively connected to a link between the driver and the receiver, where the multiple connector assemblies are interchangeably included in the link to approximate different signal-to-noise ratio margins for the link at the particular frequency.

18. The test platform of claim 17, where the crosstalk margin values of the multiple differential connector assemblies are experimentally derived.

19. The test platform of claim 17, where the particular frequency corresponds to the predominate frequency of the edge rate of the signal for the network device.

20. The test platform of claim 17, where each of the multiple differential connector assemblies include a shield structure, and where the shield structure is physically modified from original equipment manufacturer (OEM) condition to generate increased crosstalk levels.
